(19) United States
(12) Patent Application Publication
(10) Pub. No.: US 2015/0114686 A1
(43) Pub. Date: Apr. 30, 2015

(54) PRINTED CIRCUIT BOARD

(71) Applicants: HONG FU JIN PRECISION INDUSTRY (WUHAN) CO., LTD., Wuhan (CN); HON HAI PRECISION INDUSTRY CO., LTD., New Taipei (TW)

(72) Inventors: FENG-HUA DENG, Wuhan (CN); FENG ZHANG, Wuhan (CN)

(21) Appl. No.: 14/515,967

(22) Filed: Oct. 16, 2014

(30) Foreign Application Priority Data
Oct. 24, 2013 (CN) 201310504847.9

(51) Int. Cl. H05K 1/02; H05K 1/11

(52) U.S. Cl. CPC H05K 1/0213; H05K 1/115; H05K 1/0298; H05K 1/112; H05K 2201/0776
USPC 174/251

(57) ABSTRACT

A printed circuit board includes a first dielectric layer, a first ground layer, a second dielectric layer, a first power layer, a first via hole, and a first ground hole. A first signal line is laid on the first dielectric layer. A third signal line is laid on the second dielectric layer. The first and third signal lines are electrically connected to the first via hole. An extending direction of the first signal line on the first dielectric layer is opposite to an extending direction of the third signal line is laid on the second dielectric layer. A first void area is defined in the first ground layer around the first via hole. A second void area is defined in the first power layer around the first via hole. The first ground hole is outside the first void area and the second void area.

### CROSS-REFERENCE TO RELATED APPLICATIONS

This application claims priority to Chinese Patent Application No. 201310504847.9 filed on Oct. 24, 2013 in the China Intellectual Property Office, the contents of which are incorporated by reference herein.

### FIELD

The subject matter herein generally relates to a printed circuit board.

### BACKGROUND

Signal integrity is important in printed circuit boards. To ensure the signal integrity of the printed circuit boards, an impedance matching and a continuity of signal lines in the printed circuit boards are foremost.

### BRIEF DESCRIPTION OF THE DRAWINGS

Implementations of the present technology will now be described, by way of example only, with reference to the attached figures.

FIG. 1 is an exploded, isometric view of an embodiment of a printed circuit board.

FIG. 2 is an assembled, isometric view of a first via hole, a second via hole, a first signal line, a second signal line, a third signal line, and a fourth signal line of the printed circuit board of FIG. 1.

FIG. 3 is similar to FIG. 2, but viewed from another angle.

FIG. 4 is an assembled, isometric view of the printed circuit board of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

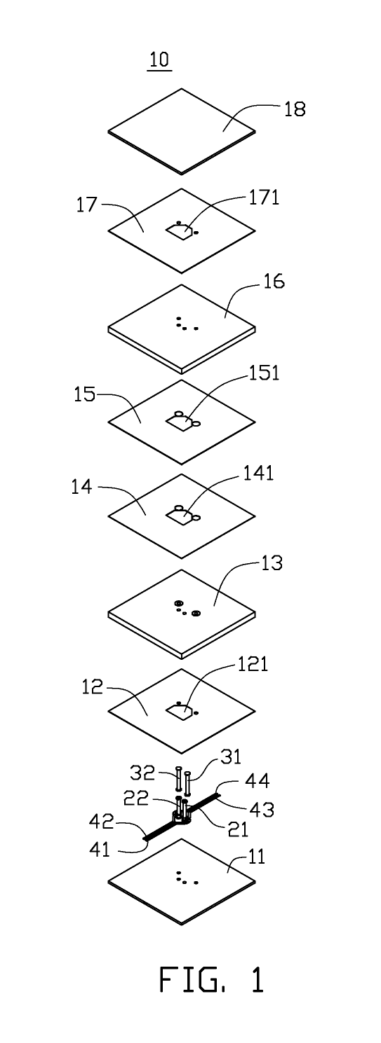

FIG. 1 illustrates a printed circuit board 10 in accordance with an embodiment. The printed circuit board 10 includes a first dielectric layer 11, a first ground layer 12, a second dielectric layer 13, a first power layer 14, a second power layer 15, a third dielectric layer 16, a second ground layer 17, and a fourth dielectric layer 18 arranged from bottom to top. The printed circuit board 10 defines a first via hole 21, a second via hole 22, a first ground hole 31, and a second ground hole 32 passing through the printed circuit board 10. A metallic material is smeared in inner surfaces of each of the first via hole 21, the second via hole 22, the first ground hole 31, and the second ground hole 32.

The first ground layer 12 defines a first void area 121 surrounding the first via hole 21 and the second via hole 22. The first ground hole 31 and the second ground hole 32 are located outside the first void area 121. The first power layer 14 defines a second void area 141 surrounding the first via hole 21 and the second via hole 22. The first ground hole 31 and the second ground hole 32 are located outside the second void area 141. Each of the first ground layer 12 and the first power layer 14 is a metallic layer. In at least one embodiment, each of the first void area 121 and the second void area 141 are substantially polygon-shaped.

The second power layer 15 defines a third void area 151 surrounding the first via hole 21 and the second via hole 22. The first ground hole 31 and the second ground hole 32 are located outside the third void area 151. The second ground layer 17 defines a fourth void area 171 surrounding the first via hole 21 and the second via hole 22. The first ground hole 31 and the second ground hole 32 are located outside the fourth void area 171. Each of the second power layer 15 and the second ground layer 17 is a metallic layer. Each of the third void area 151 and the fourth void area 171 has a same shape as the first void area 121 and the second void area 141 respectively.

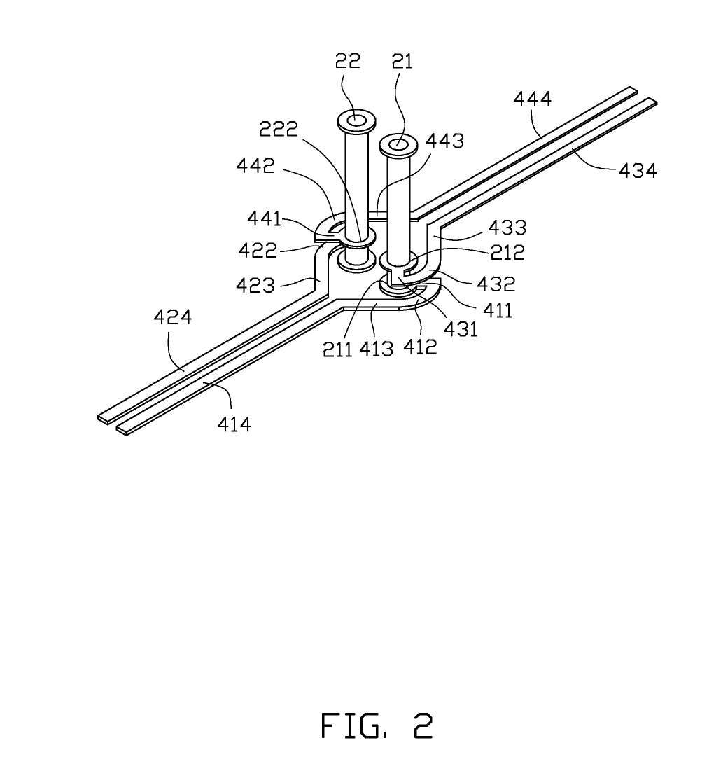

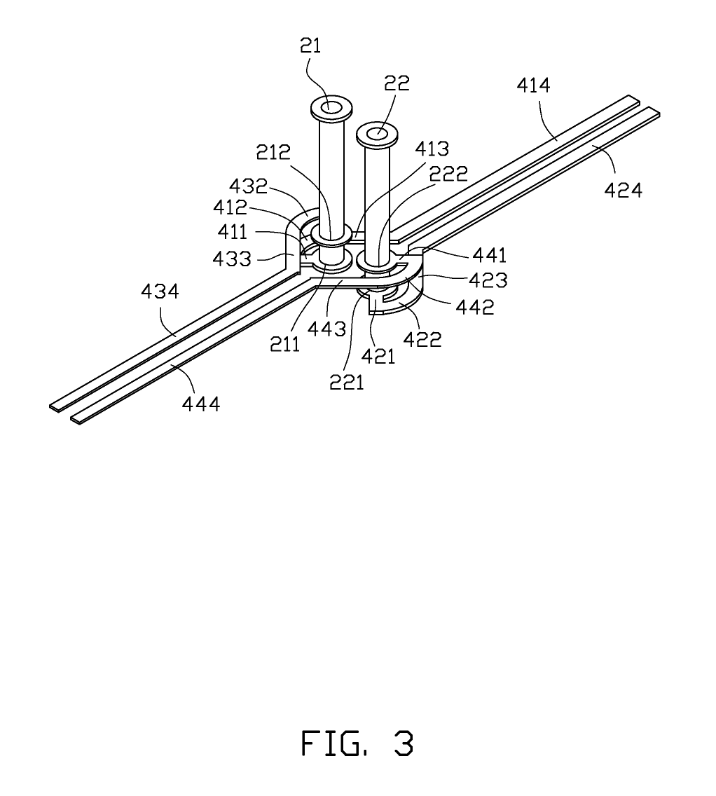

FIG. 2 illustrates the via holes and the signal lines in accordance with an embodiment. FIG. 3 illustrates the via holes and the signal lines in accordance with another embodiment. A first signal line 41 and a second signal line 42 are laid in the first dielectric layer 11. A third signal line 43 and a fourth signal line 44 are laid in the second dielectric layer 13. The first signal line 41 and the third signal line 43 are electrically coupled to the first via hole 21. The second signal line 42 and the fourth signal line 44 are electrically coupled to the second via hole 22. An extending direction of the first signal line 41 is opposite to an extending direction of the third signal line 43. An extending direction of the second signal line 42 is opposite to an extending direction of the fourth signal line 44.

A first bonding pad 211 is located on the first dielectric layer 11 and coupled to the inner surfaces of the first via hole 21. A second bonding pad 221 is located on the first dielectric layer 11 and coupled to the inner surfaces of the second via hole 22. A third bonding pad 212 is located on the second dielectric layer 13 and coupled to the inner surfaces of the first via hole 21. A fourth bonding pad 222 is located on the second dielectric layer 13 and coupled to the inner surfaces of the second via hole 22.

The first signal line 41 includes a first segment 411, a second segment 412, a third segment 413, and a fourth segment 414. The first segment 411 is electrically coupled to the first bonding pad 211. The second segment 412 is substantially arc-shaped and surrounding the first bonding pad 211. The second signal line 42 includes a fifth segment 421, a sixth segment 422, a seventh segment 423, and an eighth segment 424. The fifth segment 421 is electrically coupled to the second bonding pad 221. The sixth segment 422 is substantially arc-shaped and surrounding the second bonding pad 221. The fourth segment 414 is substantially parallel to the eighth segment 424. The first signal line 41 is coplanar with the second signal line 42.

The third signal line 43 includes a ninth segment 431, a tenth segment 432, an eleventh segment 433, and a twelfth segment 434. The ninth segment 431 is electrically coupled to the third bonding pad 212. The tenth segment 432 is substantially arc-shaped and surrounding the third bonding pad 212. The fourth signal line 44 includes a thirteenth segment 441, a fourteenth segment 442, a fifteenth segment 443, and a sixteenth segment 444. The thirteenth segment 441 is electrically coupled to the fourth bonding pad 222. The fourteenth segment 442 is substantially arc-shaped and surrounding the fourth bonding pad 222. The twelfth segment 434 is substantially parallel to the sixteenth segment 444. The third signal line 43 is coplanar with the fourth signal line 44.

Because each metallic layer defines a void area, such as the first void area 121, the second void area 141, the third void area 151, and the fourth void area 171, permittivity of the first via hole 21 and the second via hole 22 are changed. At the same time, a metallic reference plane of the first via hole 21 and the second via hole 22 is changed, causing a reference distance from each of the first via hole 21 and the second via hole 22 to the reference plane is changed. The changes of the permittivity and the reference distance cause an impedance of the first via hole 21 and the second via hole 22 to be changed.

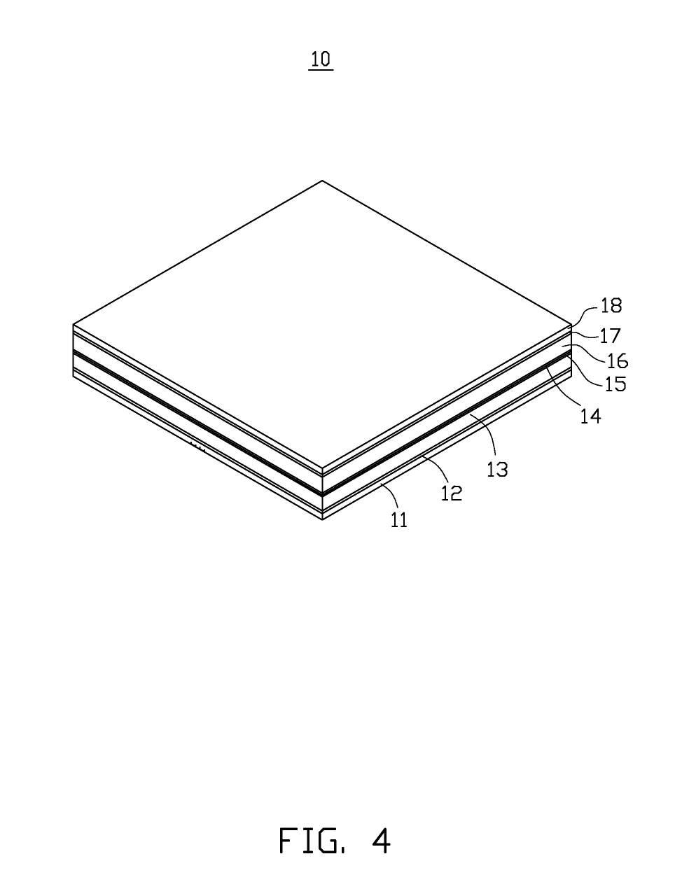

FIG. 4 illustrates when the printed circuit board 10 is assembled, a time domain reflector (not shown) is used to simulate the impedances of the first via hole 21, the second via hole 22, the first signal line 41, the second signal line 42, the third signal line 43, and the fourth signal line 44. When using the printed circuit board 10, a first impedance of the first signal line 41, the second signal line 42, the third signal line 43, and the fourth signal line 44 is 93.5 ohm, and a second impedance of the first via hole 21 and the second via hole 22 is 87.5 ohm. When testing other printed circuit boards, the first impedance is generally 89 ohm, and the second impedance is generally 69 ohm.

Thus, the second impedance in the current applicant is increased to better match the first impedance.

The embodiments shown and described above are only examples. Many details are often found in the art such as the other features of a printed circuit board. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A printed circuit board comprising:
a first dielectric layer with a first signal line laid thereon;
a first ground layer;
a second dielectric layer with a third signal line laid thereon;
a first power layer; and
a first via hole and a first ground hole extending through the first dielectric layer, the first ground layer, the second dielectric layer, and the first power layer,
wherein, the first signal line and the third signal line are electrically coupled to the first via hole, and an extending direction of the first signal line is opposite to an extending direction of the third signal line;
wherein, a first void area is defined in the first ground layer around the first via hole, and a second void area is defined in the first power layer around the first via hole; and
wherein, the first ground hole is outside the first void area and the second void area.

2. The printed circuit board of claim 1, further comprising a first bonding pad located on the first dielectric layer and electrically coupled to the first via hole, wherein the first signal line comprises a first segment, a second segment, a third segment, and a fourth segment, the first segment is electrically coupled to the first bonding pad, and the second segment surrounds the first bonding pad.

3. The printed circuit board of claim 2, further comprising a second via hole, a second ground hole, a second signal line, and a fourth signal line, wherein the second ground hole extends through the first dielectric layer, the first ground layer, the second dielectric layer, and the first power layer, the second signal line is laid on the first dielectric layer, the fourth signal line is laid on the second dielectric layer, each of the second signal line and the fourth signal line is electrically coupled to the second via hole, and the second ground hole is outside the first void area and the second void area.

4. The printed circuit board of claim 3, further comprising a second bonding pad located on the first dielectric layer and electrically coupled to the second via hole, wherein the second signal line comprises a fifth segment, a sixth segment, a seventh segment, and an eighth segment, the fifth segment is electrically coupled to the second bonding pad, and the sixth segment surrounds the second bonding pad.

5. The printed circuit board of claim 4, further comprising a third bonding pad located on the second dielectric layer and electrically coupled to the first via hole, wherein the third signal line comprises a ninth segment, a tenth segment, an eleventh segment, and a twelfth segment, the ninth segment is electrically coupled to the third bonding pad, and the tenth segment surrounds the third bonding pad.

6. The printed circuit board of claim 5, further comprising a fourth bonding pad located on the second dielectric layer and electrically coupled to the second via hole, wherein the fourth signal line comprises a thirteenth segment, a fourteenth segment, a fifteenth segment, and a sixteenth segment, the thirteenth segment is electrically coupled to the fourth bonding pad, and the fourteenth segment surrounds the fourth bonding pad.

7. The printed circuit board of claim 6, wherein each of the second segment, the sixth segment, the tenth segment, and the fourteenth segment is substantially arc-shaped.

8. The printed circuit board of claim 7, wherein the fourth segment is substantially parallel to the eighth segment, the first signal line is coplanar with the second signal line at a first plane, the twelfth segment is substantially parallel to the sixteenth segment, the third signal line is coplanar with the fourth signal line at a second plane, and the first plane is parallel to the second plane.

9. The printed circuit board of claim 8, further comprising a second power layer, a third dielectric layer, a second ground layer, and a fourth dielectric layer, wherein the second power layer defines a third void area around the first via hole and the second via hole, and each of the first ground hole and the second ground hole is outside the third void area.

10. The printed circuit board of claim 9, wherein the second ground layer defines a fourth void area around the first via hole and the second via hole, and each of the first ground hole and the second ground hole is outside the fourth void area.

11. A printed circuit board comprising:
a first dielectric layer with a first signal line laid thereon;
a first ground layer;
a second dielectric layer with a third signal line laid thereon;
a first power layer;
a first via hole and a first ground hole extending through the first dielectric layer, the first ground layer, the second dielectric layer, and the first power layer;
a first bonding pad located on the first dielectric layer and electrically coupled to the first via hole; and
a third bonding pad located on the second dielectric layer and electrically coupled to the first via hole,
wherein, the first signal line is electrically coupled to the first bonding pad, the third signal line is electrically coupled to the third bonding pad, and an extending direction of the first signal line is opposite to an extending direction of the third signal line;
wherein, a first void area is defined in the first ground layer around the first via hole, and a second void area is defined in the first power layer around the first via hole; and
wherein, the first ground hole is outside the first void area and the second void area.

12. The printed circuit board of claim 11, wherein the first signal line comprises a first segment, a second segment, a third segment, and a fourth segment, the first segment is electrically coupled to the first bonding pad, and the second segment surrounds the first bonding pad.

13. The printed circuit board of claim 12, further comprising a second via hole, a second ground hole, a second signal line, and a fourth signal line, wherein the second ground hole extends through the first dielectric layer, the first ground layer, the second dielectric layer, and the first power layer, the second signal line is laid on the first dielectric layer, the fourth signal line is laid on the second dielectric layer, each of the second signal line and the fourth signal line is electrically coupled to the second via hole, and the second ground hole is outside the first void area and the second void area.

14. The printed circuit board of claim 13, further comprising a second bonding pad located on the first dielectric layer and electrically coupled to the second via hole, wherein the second signal line comprises a fifth segment, a sixth segment, a seventh segment, and an eighth segment, the fifth segment is electrically coupled to the second bonding pad, and the sixth segment surrounds the second bonding pad.

15. The printed circuit board of claim 14, wherein the third signal line comprises a ninth segment, a tenth segment, an eleventh segment, and a twelfth segment, the ninth segment is electrically coupled to the third bonding pad, and the tenth segment surrounds the third bonding pad.

16. The printed circuit board of claim 15, further comprising a fourth bonding pad located on the second dielectric layer and electrically coupled to the second via hole, wherein the fourth signal line comprises a thirteenth segment, a fourteenth segment, a fifteenth segment, and a sixteenth segment, the thirteenth segment is electrically coupled to the fourth bonding pad, and the fourteenth segment surrounds the fourth bonding pad.

17. The printed circuit board of claim 16, wherein each of the second segment, the sixth segment, the tenth segment, and the fourteenth segment is substantially arc-shaped.

18. The printed circuit board of claim 17, wherein the fourth segment is substantially parallel to the eighth segment, the first signal line is coplanar with the second signal line at a first plane, the twelfth segment is substantially parallel to the sixteenth segment, the third signal line is coplanar with the fourth signal line at a second plane, and the first plane is parallel to the second plane.

19. The printed circuit board of claim 18, further comprising a second power layer, a third dielectric layer, a second ground layer, and a fourth dielectric layer, wherein the second power layer defines a third void area around the first via hole and the second via hole, and each of the first ground hole and the second ground hole is outside the third void area.

20. The printed circuit board of claim 19, wherein the second ground layer defines a fourth void area around the first via hole and the second via hole, and each of the first ground hole and the second ground hole is outside the fourth void area.
